(19) United States
(12) Patent Application Publication
(10) Pub. No.: US 2026/0314448 A1
(43) Pub. Date: Oct. 8, 2026

(54) ELECTRONIC DEVICE

(71) Applicant: Advanced Semiconductor Engineering, Inc., Kaohsiung (TW)

(72) Inventors: Kuofeng HUANG, Kaohsiung (TW); Hsin-Hua HUANG, Kaohsiung (TW); Cheng-Hsiang HSU, Kaohsiung (TW); Hung-Yi LIN, Kaohsiung (TW); Chi Hao CHIANG, Kaohsiung (TW); Hsin-Chin CHANG, Kaohsiung (TW)

(73) Assignee: Advanced Semiconductor Engineering, Inc., Kaohsiung (TW)

(21) Appl. No.: 19/098,970

(22) Filed: Apr. 2, 2025

(51) Int. Cl. H01L 23/538; H01L 23/367; H01L 25/07

(52) U.S. Cl. CPC H10W 70/65; H10W 40/22; H10W 70/611; H10W 90/00; H10W 90/401

(57) ABSTRACT

The present disclosure provides an electronic device. The electronic device includes a heat dissipating structure, a first conductive element, and a first electronic component. The first conductive element penetrates the heat dissipating structure. The first electronic component is disposed under the heat dissipating structure and electrically connected to the first conductive element. The heat dissipating structure is configured to provide the first electronic component with a heat transmission path without passing through the first conductive element.

### BACKGROUND

### 1. Technical Field

The present disclosure relates to an electronic device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes a heat dissipating structure, a first conductive element, and a first electronic component. The first conductive element penetrates the heat dissipating structure. The first electronic component is disposed under the heat dissipating structure and electrically connected to the first conductive element. The heat dissipating structure is configured to provide the first electronic component with a heat transmission path without passing through the first conductive element.

In some arrangements, an electronic device, a first electronic component, a first conductive element, and a first holder. The first electronic component is disposed over the first carrier. The first conductive element is disposed over the first carrier and electrically connected to the first electronic component. The first holder is disposed over the first carrier and configured to hold the first conductive element. The first holder includes a fastening profile configured to fix the first conductive element.

In some arrangements, an electronic device includes a power delivery board, a first electronic component, and a first carrier. The first electronic component is configured to receive a power from the power delivery board by a first conductive element. The first carrier is configured to receive a signal from the power delivery board by a second conductive element. A length of the first conductive element is different from a length of the second conductive element.

### BRI EF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a perspective view of an electronic device, in accordance with some arrangements of the present disclosure.

FIG. 1B illustrates an exploded view of a voltage regulated module as shown in FIG. 1A, in accordance with some arrangements of the present disclosure.

FIG. 2A illustrates a cross-sectional view along line A-A′ of an electronic device as shown in FIG. 1A, in accordance with some arrangements of the present disclosure.

FIG. 2B illustrates a cross-sectional view along line B-B′ of an electronic device as shown in FIG. 1A, in accordance with some arrangements of the present disclosure.

FIG. 3A illustrates a cross-sectional view of a heat dissipating structure and interconnections, in accordance with some arrangements of the present disclosure.

FIG. 3B illustrates a bottom view of the heat dissipating structure and interconnections of FIG. 3A, in accordance with some arrangements of the present disclosure.

FIG. 3C illustrates a top view of the heat dissipating structure and interconnections as shown in FIG. 3A, in accordance with some arrangements of the present disclosure.

FIG. 4A illustrates a cross-sectional view of an interconnection, in accordance with some arrangements of the present disclosure.

FIG. 4B illustrates a top view of the interconnection as shown in FIG. 4A, in accordance with some arrangements of the present disclosure.

FIG. 5 illustrates a top view of an interconnection, in accordance with some arrangements of the present disclosure.

FIG. 6A illustrates a cross-sectional view of an interconnection, in accordance with some arrangements of the present disclosure.

FIG. 6B illustrates a cross-sectional view of the connector as shown in FIG. 6A, in accordance with some arrangements of the present disclosure.

FIG. 6C illustrates a cross-sectional view of the conductive element as shown in FIG. 6A, in accordance with some arrangements of the present disclosure.

FIG. 7 illustrates a cross-sectional view of an electronic device, in accordance with some arrangements of the present disclosure.

FIG. 8 illustrates a cross-sectional view of an interconnection, in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

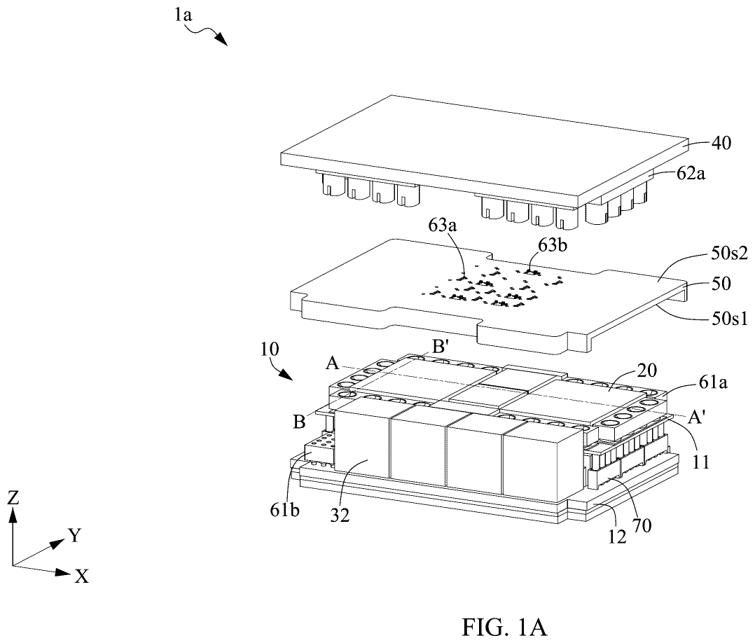

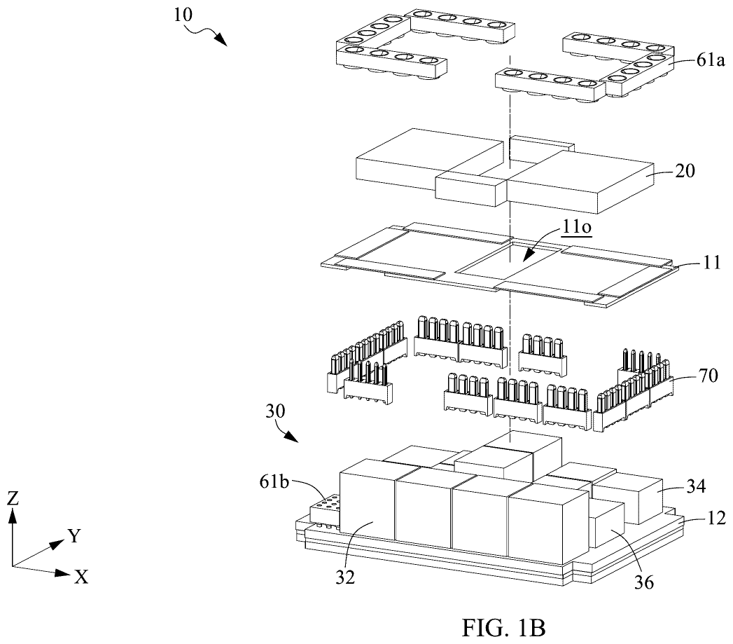

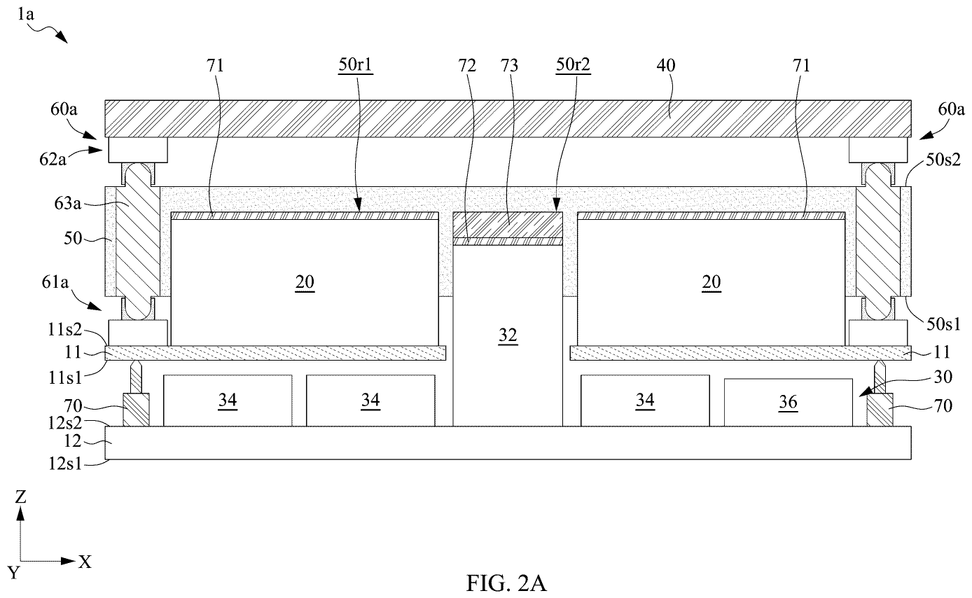

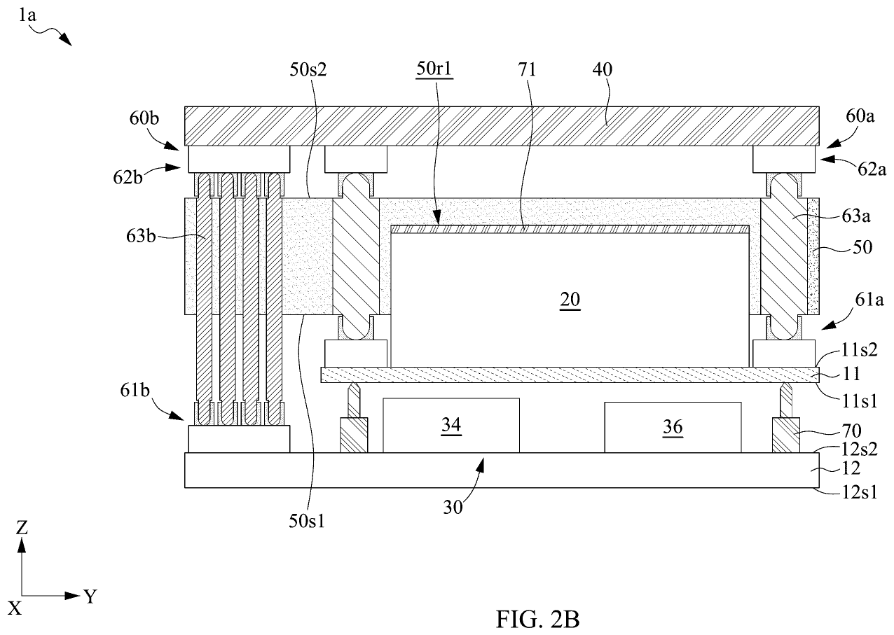

FIGS. 1A and 1B illustrate exploded views of an electronic device 1a, in accordance with some arrangements of the present disclosure. FIGS. 2A and 2B are cross-sectional views of the electronic device 1a as shown in FIG. 1A, in accordance with some arrangements of the present disclosure.

As shown in FIG. 1A, the electronic device 1a may include a voltage regulator module 10, a power delivery board 40, and a heat dissipating structure 50. In some arrangements, the voltage regulator module 10 may be configured to receive power (or a power signal) from the power delivery board 40. For example, the voltage regulator module 10 may include electronic components 20 configured to receive power from the power delivery board 40. In some arrangements, the voltage regulator module 10 may be configured to convert a higher voltage to a lower voltage.

Please refer to FIGS. 1B, 2A, and 2B, the voltage regulator module 10 may include a circuit structure 11 and a circuit structure 12 (or carriers). Each of the circuit structures 11 and 12 may be formed as a printed circuit board (PCB), flexible printed circuit board (FPCB), lead frame, a combination thereof, or other suitable circuit structures. The circuit structures 11 and 12 may be at different levels (or elevation or height) along the Z direction. Each of the circuit structures 11 and 12 may include multiple metal layers separated from one another by layers of dielectric material and interconnected by electrically conductive vias. In some embodiments, each of the circuit structures 11 and 12 may be formed of an epoxy resin, a fiberglass-reinforced epoxy resin, an epoxy resin with inorganic fillers, a ceramic material, or a polymer material such as polyimide. The circuit structure 11 may have a surface 11s1 (or lower surface) and a surface 11s2 (or upper surface) opposite to the surface 11s1. The circuit structure 12 may have a surface 12s1 (or lower surface) and a surface 12s2 (or upper surface) opposite to the surface 12s1. The circuit structure 11 may be disposed over the surface 12s2 of the circuit structure 12.

The voltage regulator module 10 may include electronic components 20. The electronic component 20 may be disposed on or over the surface 11s2 of the circuit structure 11. In some arrangements, the electronic component 20 may function as a first stage power module (or first power conversion stage or converter or electrical converter). In some arrangements, the electronic component 20 may be configured to convert a higher voltage (e.g., 48 V) to a lower voltage (e.g., 12 V). For example, the electronic component 20 may be configured to receive a higher voltage from the power delivery board 40 and transmit a lower voltage to a second stage power module 30. In some arrangements, the electronic component 20 may include at least one power module (or converter), which includes a transistor(s), a diode(s), a capacitor(s), an inductor(s), and/or other suitable elements. For example, the electronic component 20 may include a circuit structure formed as a PCB, FPCB, or other suitable circuit structures. The active components (e.g., converters, controllers, and/or drivers) and passive components (e.g., capacitors and/or inductors) may be disposed on the circuit structure.

The voltage regulator module 10 may include a second stage power module 30. The second stage power module 30 (or second power conversion stage or converter or electrical converter) may be disposed on or over the surface 12s2 of the circuit structure 12. In some arrangements, the second stage power module 30 may be configured to convert a higher voltage (e.g., 12 V) to a lower voltage (e.g., 8 V, 6 V, 4 V, 2 V, or less). In some arrangements, the second stage power module 30 may include electronic components with different thicknesses along the Z direction. For example, the second stage power module 30 may include electronic components 32, 34, and 36. The electronic components 32, 34, and 36 may have different thicknesses along the Z direction.

The electronic components 32, 34, and 36 may be disposed on or over the surface 12s2 of the circuit structure 12. The electronic components 34 and 36 may be disposed within a space defined by the circuit structures 11 and 12. In some arrangements, the electronic component 32 may be disposed within an opening 11o defined by the circuit structure 11. In some arrangements, a portion of the electronic component 32 may be protruded from the surface 11s2 of the circuit structure 11. In some arrangements, the thickness (e.g., the length along the Z direction) of the electronic component 32 may be greater than that of the electronic component 20. In some arrangements, each of the electronic components 34 and 36 may have a thickness (e.g., the length along the Z direction) less than that of the electronic component 20. In some arrangements, the thickness of the electronic component 32 may be greater than or equal to 7 mm, such as 7 mm, 8 mm, 9 mm, 10 mm, or more. In some arrangements, the thickness of the electronic component 20 may range between 3 mm and 7 mm, such as 3 mm, 4 mm, 5 mm, 6 mm, or 7 mm. The thickness of the electronic components 34 or 36 may range between about 1 mm and 5 mm, such as 1 mm, 2 mm, 3 mm, 4 mm, or 5 mm. The electronic components 32 and 34 (or voltage regulators or converters) may be configured to convert a higher voltage (e.g., 12 V) to a lower voltage (e.g., 8 V, 6 V, 4 V, 2 V, or less). The electronic components 32 and 34 may be electrically connected to the circuit structure 11. The electronic components 32 and 34 may include multiple elements on a circuit structure (e.g., PCB). For example, the electronic components 32 and 34 may include a transistor(s), a controller(s), and a passive element(s). The electronic component 36 may be configured to turn on or turn off the electronic component 32 and/or 34. For example, the electronic component 36 may function as a controller. It should be noted that the second stage power module 30 may include more components, such as passive elements (e.g., capacitors and/or inductors), active components, and/or other suitable components.

In some arrangements, the electronic device 1a may include interconnections 60a. In some arrangements, the interconnection 60a may be configured to transmit power between the voltage regulator module 10 and the power delivery board 40. In some arrangements, the interconnection 60a may include a connector 61a, a connector 62a, and a conductive element 63a.

In some arrangements, the connector 61a may be disposed on or over the surface 11s2 of the circuit structure 11. In some arrangements, the connector 61a may be configured to connect, hold, or accommodate conductive element 63a. For example, the connector 61a may define a recess for accommodating a portion of the conductive element 63a.

In some arrangements, the connector 62a may be disposed on or under the power delivery board 40. In some arrangements, the connector 62a may be configured to connect, hold, or accommodate the conductive element 63a. For example, the connector 62a may define a recess for accommodating a portion of the conductive element 63a.

In some arrangements, the conductive element 63a may be connected between the connectors 61a and 62a. The conductive element 63a may be disposed on or over the surface 11s2 of the circuit structure 11. In some arrangements, the conductive element 63a may be configured to transmit power (or power signal) between the voltage regulator module 10 and power delivery board 40. For example, the conductive element 63a may be configured to transmit a relatively great power (e.g., 48 V) from the power delivery board 40 to the electronic component 20. In some arrangements, the conductive element 63a may be fixed to the heat dissipating structure 50. In some arrangements, the conductive element 63a may penetrate the heat dissipating structure 50. In some arrangements, the conductive element 63a may include a pogo pin, conductive pillar, or other suitable conductive elements.

In some arrangements, the electronic device 1a may include interconnections 60b. In some arrangements, the interconnection 60b may be configured to transmit a signal (or data signal) between the voltage regulator module 10 and the power delivery board 40. In some arrangements, the interconnection 60b may include a connector 61b, a connector 62b, and a conductive element 63b.

In some arrangements, the connector 61b may be disposed on or over the surface 12s1 of the circuit structure 12. In some arrangements, the connectors 61a and 61b may be located at different levels (or heights or elevations) along the Z direction. In some arrangements, the connector 61b may be configured to connect, hold, or accommodate conductive element 63b. For example, the connector 61b may define a recess for accommodating a portion of the conductive element 63b.

In some arrangements, the connector 62b may be disposed on or under the power delivery board 40. In some arrangements, the connectors 62a and 62b may be located at the same level (or height or elevation) along the Z direction. In some arrangements, the connector 62b may be configured to connect, hold, or accommodate the conductive element 63b. For example, the connector 62b may define a recess for accommodating a portion of the conductive element 63b.

In some arrangements, the conductive element 63b may be connected between the connectors 61b and 62b. The conductive element 63b may be disposed on or over the surface 12s2 of the circuit structure 12. In some arrangements, the conductive element 63b may be configured to transmit a signal between the voltage regulator module 10 and power delivery board 40. For example, the conductive element 63b may be configured to transmit a signal from the power delivery board 40 to the circuit structure 12. In some arrangements, the conductive element 63b may be fixed to the heat dissipating structure 50. In some arrangements, the conductive element 63b may penetrate the heat dissipating structure 50. In some arrangements, the conductive element 63b may include a pogo pin, conductive pillar, or other suitable conductive elements.

In some arrangements, the power delivery board 40 may be configured to provide the voltage regulator module 10 with a relatively great power (e.g., 48 V). In some arrangements, the power delivery board 40 may be configured to transmit a signal (e.g., data signal) to the voltage regulator module 10. In some arrangements, the power delivery board 40 may include a PCB, FPCB, or other suitable circuit structures. One or more electronic components (not shown) may be disposed on or over the power delivery board 40. For example, the electronic device 1a may include a power management integrated circuit (PMIC) die on or within the power delivery board 40.

In some arrangements, the heat dissipating structure 50 may be disposed between the voltage regulator module 10 and the power delivery board 40. In some arrangements, the heat dissipating structure 50 may be thermally coupled to the voltage regulator module 10. For example, the heat dissipating structure 50 may be configured to transmit heat from the voltage regulator module 10. In some arrangements, the heat dissipating structure 50 may be thermally coupled to the power delivery board 40. For example, the heat dissipating structure 50 may be configured to transmit heat from the power delivery board 40. The heat dissipating structure 50 may include a cold plate, which may include a vapor chamber, heat pipe, and/or other suitable elements. The heat dissipating structure 50 may include thermal conductive materials, such as aluminum (Al), copper (Cu), chromium (Cr), tin (Sn), gold (Au), silver (Ag), nickel (Ni) or stainless steel, or a mixture, an alloy, or other combinations thereof. The heat dissipating structure 50 may have a surface 50s1 (e.g., lower surface) and a surface 50s2 (e.g., upper surface) opposite to the surface 50s1. The surface 50s1 may face the voltage regulator module 10. The surface 50s2 may face the power delivery board 40. As shown in FIGS. 2A and 2B, the connectors 61a and 61b may be disposed on or under the surface 50s1 of the heat dissipating structure 50, and the connectors 62a and 62b may be disposed on or over the surface 50s1 of the heat dissipating structure 50.

In some arrangements, the heat dissipating structure 50 may define a recess 50r1 and a recess 50r2. The recess 50r1 may be recessed from the surface 50s1 of the heat dissipating structure 50. The recess 50r2 may be recessed from the surface 50s1 of the heat dissipating structure 50. In some arrangements, the recess 50r1 may be configured to accommodate the electronic component 20, thereby enhancing the heat dissipation performance. In some arrangements, the recess 50r2 may be configured to accommodate the electronic component 32, thereby enhancing the heat dissipation performance. In some arrangements, the recesses 50r1 and 50r2 may be spaced apart from each other. In other arrangements, the recess 50r1 may be connected to the recess 50r2, thereby defining an opening accommodating the electronic components 20 and 32. In some arrangements, the recesses 50r1 and 50r2 may have the same depth along the Z direction. In some arrangements, the recesses 50r1 and 50r2 may have different depths along the Z direction. For example, the recess 50r1 may have a depth greater than that of the recess 50r2. In some arrangements, the heat dissipating structure 50 may be configured to provide the electronic component 20 with a heat transmission path without passing through the conductive element 63a. In some arrangements, the heat dissipating structure 50 may be configured to provide the electronic component 20 with a heat transmission path without passing through the circuit structure 11.

In some arrangements, the electronic device 1a may include interconnections 70. In some arrangements, the interconnections 70 may be disposed on or over the surface 12s2 of the circuit structure 12. The interconnections 70 may be disposed at a peripheral region of the circuit structure 12. For example, the interconnections 70 may surround the electronic components 32, 34, and 36. The interconnections 70 may be disposed between the circuit structures 11 and 12. In some arrangements, the interconnections 70 may be configured to support the circuit structure 11. In some arrangements, the interconnections 70 may electrically connect the circuit structures 11 and 12. In some arrangements, the interconnections 70 may be configured to transmit power and/or signal. In some arrangements, the interconnections 70 may include a pogo pin, conductive pillar, or other suitable conductive elements. In other arrangements, the interconnections 70 may be replaced by an interposer(s), which may include a substrate (e.g., silicon substrate or other substrate) and conductive elements (e.g., through silicon via (TSV)) in the substrate. In other arrangements, the interconnections 70 may be replaced by other conductive components, such as solder materials.

In some arrangements, the electronic device 1a may include a thermally conductive layer 71. The thermally conductive layer 71 may be disposed on or over the electronic component 20. For example, the thermally conductive layer 71 may be disposed on or over the upper surface of the electronic component 20. In other arrangements, the thermally conductive layer 71 may be disposed on the lateral surface (or side) of the electronic component 20. The thermally conductive layer 71 may be disposed between the electronic component 20 and the heat dissipating structure 50. The thermally conductive layer 71 may be configured to transmit heat between the electronic component 20 and the heat dissipating structure 50. In some arrangements, the interconnections 70 may include a thermal conductive material, such as thermal interface material (TIM), thermal conductive paste, or other suitable materials. In some arrangements, metallic particles, such as silver or gold, may be doped within the thermally conductive layer 71. In other arrangements, the thermally conductive layer 71 may be omitted, and the electronic component 20 may be in direct contact with the heat dissipating structure 50.

In some arrangements, the electronic device 1a may include a thermally conductive layer 72. The thermally conductive layer 72 may be disposed on or over the electronic component 32. For example, the thermally conductive layer 72 may be disposed on or over the upper surface of the electronic component 32. In other arrangements, the thermally conductive layer 72 may be disposed on the lateral surface (or side) of the electronic component 32. The thermally conductive layer 72 may be disposed between the electronic component 32 and the heat dissipating structure 50. The thermally conductive layer 72 may be configured to transmit heat between the electronic component 32 and the heat dissipating structure 50. In some arrangements, the thermally conductive layer 72 may include a thermal conductive material, such as thermal interface material, thermal conductive paste, or other suitable materials. In some arrangements, metallic particles, such as silver or gold, may be doped within the thermally conductive layer 72.

In some arrangements, the electronic device 1a may include a spacer 73. In some arrangements, the spacer 73 may be disposed within the recess 50r2 of the heat dissipating structure 50. In some arrangements, the spacer 73 may be disposed between the electronic component 32 and the heat dissipating structure 50. The spacer 73 may be configured to transmit heat between the electronic component 32 and the heat dissipating structure 50. The spacer 73 may include a thermal conductive material, such as metal or alloy. In other arrangements, the spacer 73 and the heat dissipating structure 50 may be formed in one piece. In some arrangements, the heat dissipating structure 50 may be configured to provide the electronic component 32 with a heat transmission path without passing through the conductive element 63a. In some arrangements, the heat dissipating structure 50 may be configured to provide the electronic component 32 with a heat transmission path without passing through the circuit structure 12.

In this arrangement, the electronic device 1a includes interconnections 60a and 60b for transmitting power and signals. In some cases, the current flowing through conductive element 63a exceeds that flowing through conductive element 63b. Consequently, if the transmission path is excessively long, the interconnection responsible for power transmission may experience greater power loss. In this configuration, electronic component 20 is positioned closer to the power delivery board 40 than the second stage power module 30. Additionally, the length of conductive element 63a is shorter than that of conductive element 63b, resulting in a reduced transmission path for power. As a result, power loss can be minimized.

In this arrangement, the heat dissipating structure 50 may define one or more recesses (e.g., recesses 50r1 and 50r2) for accommodating the electronic component 20 and 32, which enhances the heat dissipating performance of the electronic device 1a. Additionally, the presence of recesses 50r1 and 50r2 contributes to a reduction in the overall thickness (i.e., the dimension along the Z direction) of the electronic device 1a.

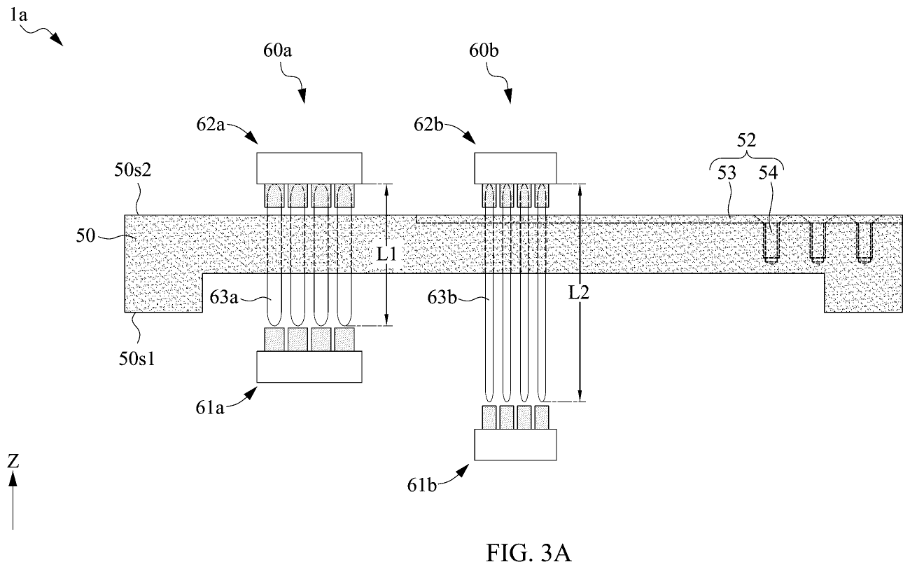

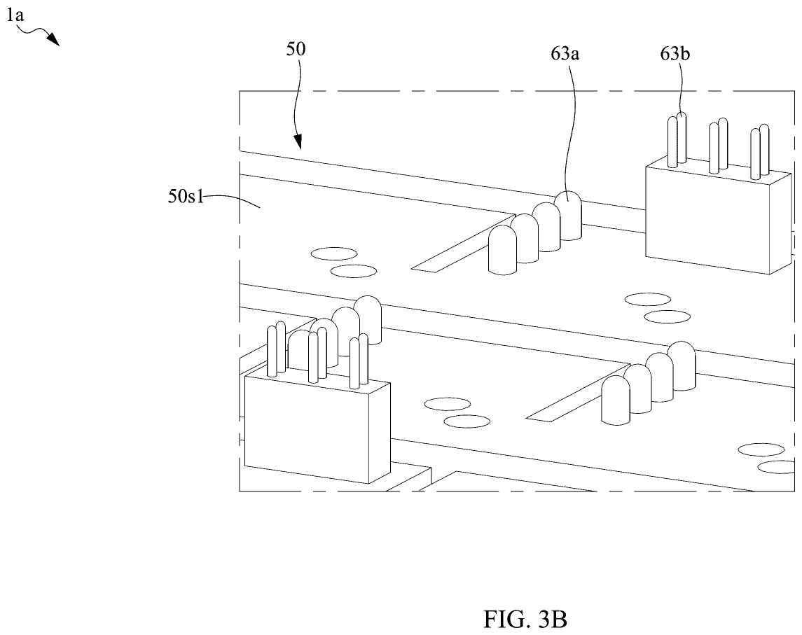

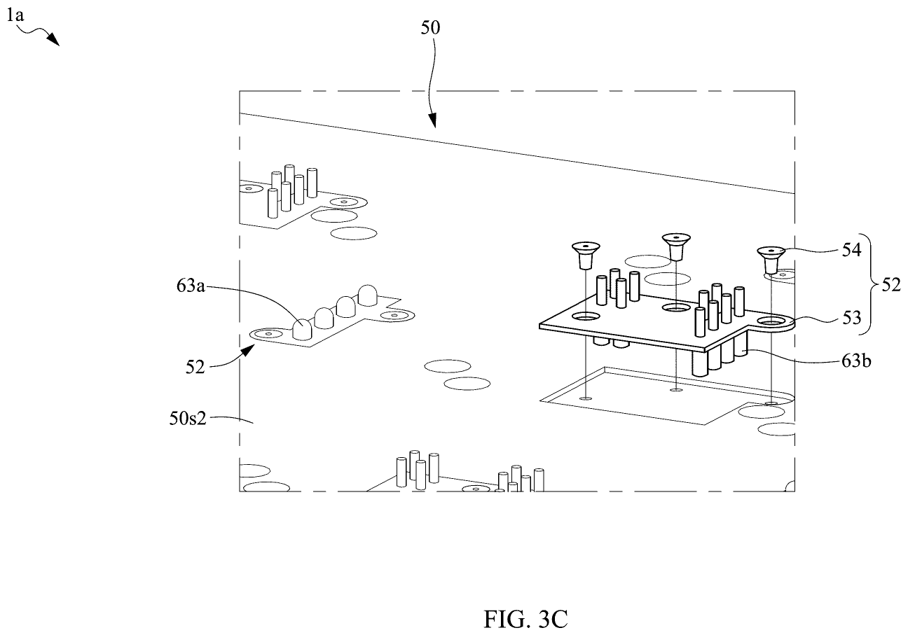

FIGS. 3A, 3B, and 3C illustrate the heat dissipating structure 50, interconnections 60a, and 60b, in accordance with some arrangements of the present disclosure.

As shown in FIG. 3A, the conductive element 63a may have a length L1 along the Z direction. The conductive element 63b may have a length L2 along the Z direction. In some arrangements, the length L2 may be greater than the length L1. In some arrangements, the conductive element 63a may have a diameter (or width) greater than that of the conductive element 63b. As shown in FIG. 3B, in some arrangements, the interconnection 60b may include a housing 55 for accommodating or fixing a portion of the conductive element 63b. The conductive elements 63a and 63b may have protruding portions of different lengths protruded from the surface 50s1.

As shown in FIGS. 3A and 3C, the electronic device 1a may include fixing modules 52 (or fastening modules). In some arrangements, the fixing module 52 may abut the surface 50s2 of the heat dissipating structure 50. In some arrangements, the fixing module 52 may be partially embedded within the heat dissipating structure 50. In some arrangements, the fixing module 52 may be configured to fix the interconnection 60a and/or 60b to the heat dissipating structure 50. In some arrangements, the fixing module 52 may be configured to fix the conductive element 63a and/or 63b to the heat dissipating structure 50. As shown in FIG. 3C, the fixing module 52 may include a base 53 and fasteners 54. In some arrangements, the heat dissipating structure 50 may define recesses for accommodating the base 53. The base 53 may include a plate which defines a plurality of holes for accommodating the fastener 54, conductive element 63a, and/or conductive element 63b. In some arrangements, the fastener 54 may penetrate the base 53. In some arrangements, the fastener 54 may penetrate the heat dissipating structure 50. In some arrangements, the fastener 54 may include a screw, pin, or other suitable elements. In some arrangements, the lower surfaces of the connectors 62a and 62b may be attached to or abut the surface 50s2 after the interconnections 60a and 60b are fixed to the heat dissipating structure 50 by the fixing module 52.

In some cases, the conductive elements 63a and 63b may become tilted if the lengths of their protruding portions exceed a certain length (e.g., greater than 7 mm or more) or if the depths of the connectors 61a, 61b, 62a, and 62b are insufficient (e.g., less than 3 mm). To address this issue, the fixing module 52 is designed to secure the interconnections 60a and 60b. As a result, the conductive elements 63a and 63b can remain properly aligned, even in the presence of a significant length discrepancy between them.

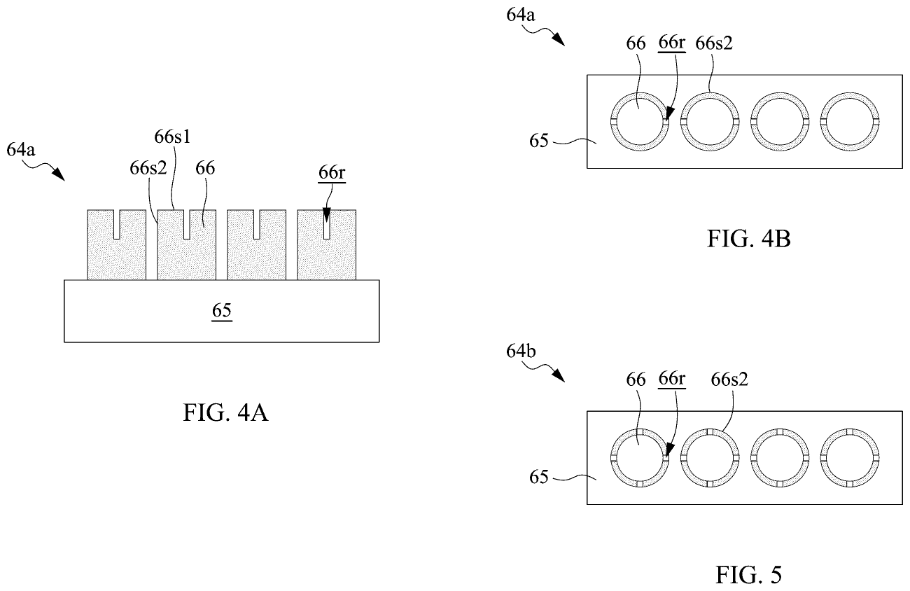

FIGS. 4A and 4B illustrate a cross-sectional view of a connector 64a, in accordance with some arrangements of the present disclosure. In some arrangements, the connectors 61a, 61b, 61c, and 61d may have a structure the same as or similar to that of the connector 64a.

The connector 64a may include a base 65 and holders 66 on the base 65. The base 65 may include a dielectric structure and conductive traces within the dielectric structure. The holder 66 (or receiver) may be configured to connect, hold, or accommodate the conductive element 63a (or conductive element 63b) as shown in FIGS. 2A and 2B. In some arrangements, the holder 66 may include a hollow portion for accommodating the conductive element 63a (or conductive element 63b). In some arrangements, the holder 66 may have a surface 66s1 and a surface 66s2 (or side or lateral surface). In some arrangements, the holder 66 may have recesses 66r recessed from the surface 66s1. In some arrangements, the recess 66r may be configured to fix the conductive element 63a (or conductive element 63b). The recess 66r may be configured to allow the holder 66 to be enlarged when the conductive element 63a (or conductive element 63b) is inserted into the holder 66. As shown in FIG. 4B the connector 64a may include two recess 66r at opposite sides of the surface 66s2. In other arrangements, the recess 66r may be disposed at the same semicircular area from a top view.

FIG. 5 illustrates a top view of a connector 64b, in accordance with some arrangements of the present disclosure. The connector 64b may include a structure similar to that of the connector 64a, with the difference that the connector 64b may include four recess 66r that are evenly spaced around the periphery of surface 66s2. In some arrangements, the connectors 61a, 61b, 61c, and 61d may have a structure the same as or similar to that of the connector 64b.

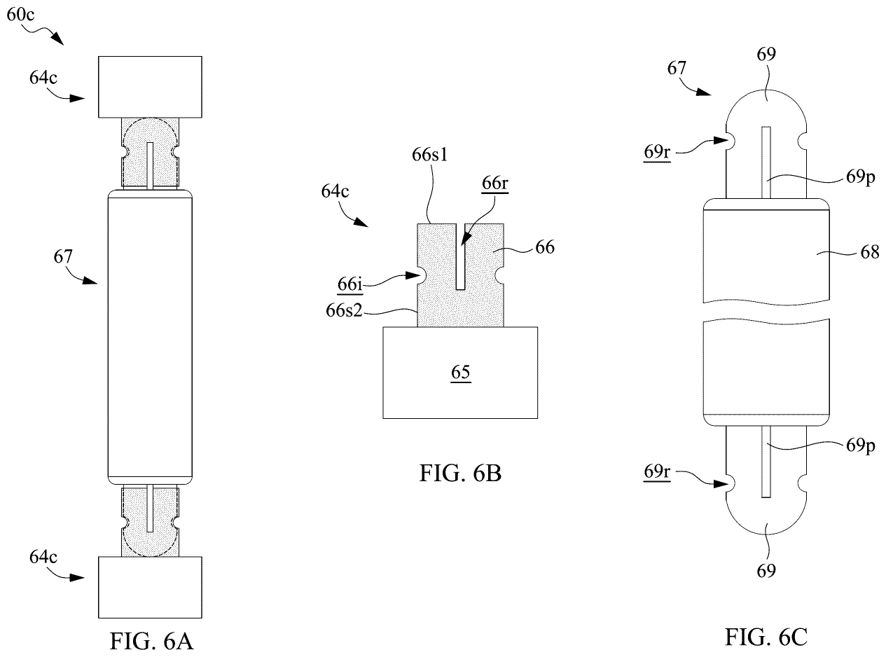

FIGS. 6A, 6B, and 6C illustrate partial enlarged views of an interconnection 60c, in accordance with some arrangements of the present disclosure. In some arrangements, the interconnections 60a and 60b as shown in FIGS. 1A to 2B may be replaced by the interconnection 60c.

As shown in FIGS. 6A and 6B, the interconnection 60c may include connectors 64c. The connector 64c may have a structure the same as or similar to that of the connector 64a or connector 64b, with the difference that the connector 64c may include indentations 66i (or notches). In some arrangements, the indentations 66i may be recessed from the surface 66s2 of the holder 66. The indentations 66i may be configured to fix the conductive element 67. The indentations 66i may have any suitable profiles for matching the conductive element 67.

As shown in FIGS. 6A and 6C, the conductive element 67 may include a sleeve 68 and terminals 69. The terminals 69 may be disposed on two opposite sides of the sleeve 68. The terminals 69 may be inserted into the connector 64c. The terminals 69 may include a plug 69p and indentations 69r (or notches). In some arrangements, the plug 69p may be configured to fit or match the profile of the recess 66r. In some arrangements, the indentations 69r may be configured to fit or match the profile of the indentations 66i.

In this arrangement, the conductive element 67 can be securely attached to the connector 64c using appropriate fixing patterns, such as the indentations 66i, recess 66r, plug 69p, and/or indentations 69r. As a result, the conductive element 67 remains stable and is not prone to tilting.

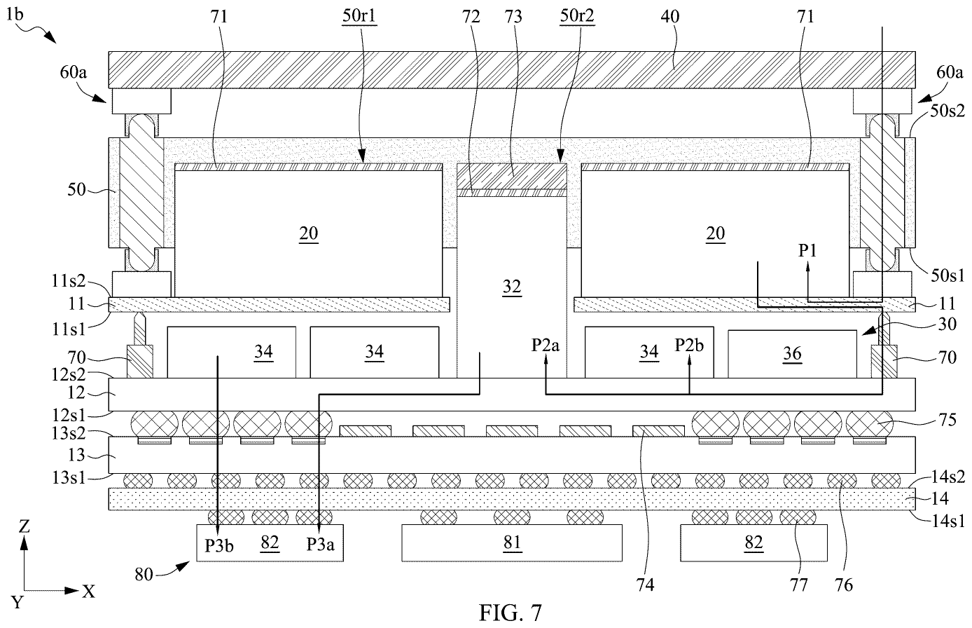

FIG. 7 illustrates a cross-sectional view of an electronic device 1b, in accordance with some arrangements of the present disclosure. The electronic device 1b is similar to the electronic device 1a, differing as follows.

In some arrangements, the electronic device 1b may include a circuit structure 13. In some arrangements, the circuit structure 13 may be formed as a printed circuit board, flexible printed circuit board, or other suitable circuit structures. The circuit structure 13 may include multiple metal layers separated from one another by layers of dielectric material and interconnected by electrically conductive vias. In some embodiments, the circuit structure 13 may be formed of an epoxy resin, a fiberglass-reinforced epoxy resin, an epoxy resin with inorganic fillers, a ceramic material, or a polymer material such as polyimide. The circuit structure 13 may have a surface 13s1 (or lower surface) and a surface 13s2 (or upper surface) opposite to the surface 13s1. The surface 13s2 of the circuit structure 13 may face the surface 12s1 of the circuit structure 12.

In some arrangements, the electronic device 1b may include passive components 74. The passive components 74 may be disposed on or over the surface 13s2 of the circuit structure 13. The passive components 74 may be electrically connected to the circuit structure 12. In some arrangements, the passive components 74 may be disposed between the circuit structures 12 and 13. The passive components 74 may be electrically connected to the circuit structure 13. In some arrangements, the passive components 74 may be configured to regulate the power from the second stage power module 30 toward an operating module 80 (or computing module). In some arrangements, the passive components 74 may include capacitors. In some arrangements, the passive components 74 may include an input capacitor (Cin) through which the power flows before being delivered to the second stage power module 30 (e.g., the electronic component 32). In some arrangements, the passive components 74 may include an output capacitor (Cout) through which the power flows after being transmitted from the second stage power module 30 (e.g., the electronic component 32).

The electronic device 1b may include electrical connectors 75. The electrical connectors 75 may be between the circuit structures 12 and 13. The electrical connectors 75 may be or include electrical contacts, such as solder balls (e.g., controlled collapse chip connection (C4) bumps, a ball grid array (BGA), a land grid array (LGA)), conductive bumps, or the like. The electrical connectors 75 may include alloys of gold and tin solder or alloys of silver and tin solder, or other suitable materials.

The electronic device 1b may include a carrier 14 (or substrate). In some arrangements, the carrier 14 may be disposed on or under the surface 13s1 of the circuit structure 13. In some arrangements, the carrier 14 may include a semiconductor substrate, such as silicon, germanium, and other group III-V and group IV materials. The carrier 14 may include metal lines and vias, including but not limited to through-silicon vias (TSVs) for interconnection. In some arrangements, the carrier 14 may include a wafer, a panel form or other suitable forms. The carrier 14 may have a surface 14s1 (or a lower surface) and a surface 14s2 (or an upper surface) opposite to the surface 14s1.

The carrier 14 may be electrically connected to the circuit structure 13 through electrical connectors 76. The carrier 14 may be configured to support the operating module 80. In some arrangements, the electrical connectors 76 may include a reflowable material. The electrical connectors 76 may be or include electrical contacts, such as solder balls (e.g., controlled collapse chip connection (C4) bumps, a ball grid array (BGA), a land grid array (LGA)), conductive bumps, or the like. The electrical connectors 76 may include alloys of gold and tin solder or alloys of silver and tin solder, or other suitable materials.

In some arrangements, the operating module 80 may be disposed on or under the surface 14s1 of the carrier 14. In some arrangements, the operating module 80 may be configured to generate non-power signals, such as analog signals, digital signals, clock signals or other electrical signals other than power signals. The operating module 80 may include electronic components 81 and 82. In some arrangements, the electronic components 81 and 82 may be disposed on or under the surface 14s1 of the carrier 14. In some arrangements, the electronic component 81 may include a processor or other suitable components. In some arrangements, the electronic component 81 may include an active device, such as a central processing unit (CPU), a microprocessor unit (MPU), a graphics processing unit (GPU), a microcontroller unit (MCU), a radio frequency integrated circuit (RFIC), an application-specific IC (ASIC), a field-programmable gate array (FPGA), or another type of IC. In some arrangements, the electronic component 82 may include a data storage unit or other suitable components. The electronic component 82 may be electrically connected to the electronic component 81 through the carrier 14. The electronic component 82 may be disposed on or under the surface 14s1 of the carrier 14. In some arrangements, the electronic component 82 may be configured to store the signals from the electronic component 81 and/or other devices. In some arrangements, the electronic component 82 may include a high band memory (HBM) die, dynamic random access memory (DRAM) die, static random access memory (SRAM) die, or other suitable memory devices. In some arrangements, the operating module 80 may further include other components, such as input/output dies configured to receive regulated power from the second stage power module 30 and/or transmit a processed signal to other devices (not shown). The electronic components 81 and 82 may be electrically connected to the carrier 14 by electrical connectors 77. In some arrangements, the electrical connectors 77 may include a reflowable material. The electrical connectors 77 may be or include electrical contacts, such as solder balls (e.g., controlled collapse chip connection (C4) bumps, a ball grid array (BGA), a land grid array (LGA)), conductive bumps, or the like. The electrical connectors 77 may include alloys of gold and tin solder or alloys of silver and tin solder, or other suitable materials. In other arrangements, the electronic components 81 and 82 may be electrically connected to the carrier 14 by hybrid-bond techniques, which involve a bonding between metallic materials (e.g., a bonding between copper and copper) and a bonding between dielectric materials (e.g., a bonding between oxide and oxide).

In some arrangements, the interconnection 60a may be configured to receive a power P1 (or voltage or external power) from the power delivery board 40. In some arrangements, the circuit structure 11 may be configured to provide the electrical path (or power path) conducting the power P1.

The circuit structure 11, circuit structure 12, and interconnections 70 may be configured to provide the electrical path (or power path) conducting the powers P2a and P2b from the electronic component 20. In some arrangements, the electronic component 32 may be configured to receive the power P2a from the electronic component 20 through the circuit structure 11, circuit structure 12, and interconnections 70. In some arrangements, the electronic component 34 may be configured to receive the power P2b from the circuit structure 11, circuit structure 12, and interconnections 70. In some arrangements, the power P2a may be substantially the same as the power P2b.

The operating module 80 may be configured to receive powers P3a and P3b (or regulated powers) from the second stage power module 30 (e.g., electronic components 32 and 34). In some arrangements, the circuit structure 12 may be configured to provide the electrical path (or power path) conducting the powers P3a and P3b. In some arrangements, the circuit structure 13 may be configured to provide the electrical path (or power path) conducting the powers P3a and P3b. In some arrangements, the carrier 14 may be configured to provide the electrical path (or power path) conducting the powers P3a and P3b. In some arrangements, the second stage power module 30 may provide the operating module 80 with powers at different levels (e.g., 8 V, 6 V, 4 V, 2 V, or less). For example, the power P3a may be different from the power P3b.

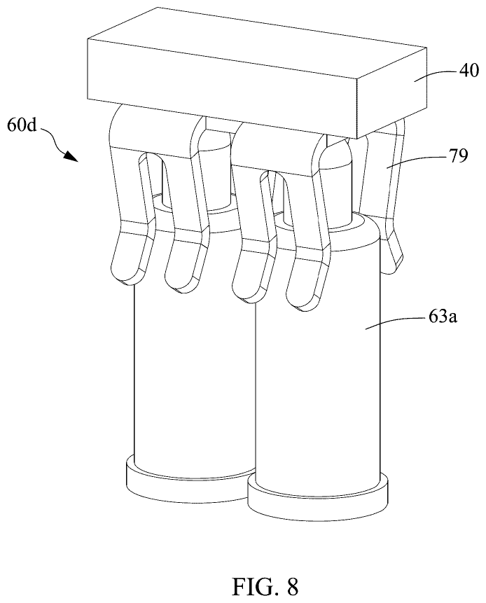

FIG. 8 illustrates a cross-sectional view of an interconnection 60d, in accordance with some arrangements of the present disclosure. In some arrangements, the interconnection 60d is similar to the interconnection 60a, differing as follows.

In some arrangements, the connector 61a (or connector 62a) may be replaced by a fixing module 79. In some arrangements, the fixing module 79 may be attached to the power delivery board 40. In some arrangements, the sleeve 68 may be configured to fix, grab, or hold the conductive element 63a. The sleeve 68 may include, for example, a clip, hasp, or other suitable elements.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a heat dissipating structure;
a first conductive element penetrating the heat dissipating structure; and
a first electronic component disposed under the heat dissipating structure and electrically connected to the first conductive element,
wherein the heat dissipating structure is configured to provide the first electronic component with a heat transmission path without passing through the first conductive element.

2. The electronic device of claim 1, wherein the heat dissipating structure defines a recess accommodating the first electronic component.

3. The electronic device of claim 1, further comprising:
a power delivery board over the heat dissipating structure and configured to provide the first electronic component with a first power of a first voltage.

4. The electronic device of claim 3, further comprising:
a first carrier supporting the first electronic component; and
a first connector disposed over the first carrier and configured to hold the first conductive element.

5. The electronic device of claim 4, further comprising:
a second connector disposed under the power delivery board and configured to hold the first conductive element.

6. The electronic device of claim 4, further comprising:
a second electronic component configured to receive a second power, from the first electronic component, of a second voltage less than the first voltage; and
a second carrier disposed under the first carrier and configured to support the second electronic component.

7. The electronic device of claim 6, further comprising a second conductive element extending between the power delivery board and the second carrier, wherein a dimension of the second conductive element is different from a dimension of the first conductive element.

8. The electronic device of claim 6, further comprising a second conductive element configured to transmit a signal between the power delivery board and the second carrier.

9. The electronic device of claim 6, wherein the second electronic component has a portion protruding from the first carrier toward the heat dissipating structure.

10. The electronic device of claim 3, further comprising a fastener configured to fix the first conductive element to the heat dissipating structure, wherein the fastener is closer to the power delivery board than to the first electronic component.

11. An electronic device, comprising:
a first carrier;
a first electronic component disposed over the first carrier;
a first conductive element disposed over the first carrier and electrically connected to the first electronic component; and
a first connector disposed over the first carrier and configured to hold the first conductive element,
wherein the first connector comprises a fastening profile configured to fix the first conductive element.

12. The electronic device of claim 11, wherein the fastening profile comprises a recess recessed from an upper surface of the first connector.

13. The electronic device of claim 11, further comprising:
a power delivery board configured to transmit a power to the first electronic component through the first conductive element.

14. The electronic device of claim 11, further comprising:
a second carrier under the first carrier; and
a second electronic component over the second carrier and configured to receive a first regulated power of a first voltage from the first electronic component.

15. The electronic device of claim 14, further comprising:
a third electronic component between the second carrier and the first carrier and configured to receive a second regulated power of a second voltage from the first electronic component, wherein the first voltage is substantially equivalent to the second voltage.

16. An electronic device, comprising:
a power delivery board;
a first electronic component configured to receive a power from the power delivery board by a first conductive element; and
a first carrier configured to receive a signal from the power delivery board by a second conductive element,
wherein a length of the first conductive element is different from a length of the second conductive element.

17. The electronic device of claim 16, further comprising:
a heat dissipating structure between the first electronic component and the power delivery board; and
a fastening module at least partially between the heat dissipating structure and the power delivery board, wherein the fastening module is configured to fix the first conductive element to the heat dissipating structure.

18. The electronic device of claim 16, further comprising:
a second carrier over the first carrier and supporting the first electronic component; and
a first connector on the second carrier and configured to hold the first conductive element.

19. The electronic device of claim 18, further comprising:
a second connector on the first carrier and configured to hold the first conductive element.

20. The electronic device of claim 16, further comprising:
a second electronic component on the first carrier and configured to receive a regulated power from the first electronic component.
